(19) United States
(12) Patent Application Publication
(10) Pub. No.: US 2026/0289379 A1
(43) Pub. Date: Sep. 24, 2026

(54) OPTIMISING BELIEF PROPAGATION DECODING FOR QEC CODES

(71) Applicant: PHOTONIC INC., Coquitlam (CA)

(72) Inventors: Daryus CHANDRA, New Westminster (CA); Patricio FUENTES, New Westminster (CA); Joschka ROFFE, Edinburgh (GB)

(21) Appl. No.: 19/040,677

(22) Filed: Jan. 29, 2025

Related U.S. Application Data
(60) Provisional application No. 63/627,690, filed on Jan. 31, 2024.

(51) Int. Cl. G06N 10/70; H03M 13/11

(52) U.S. Cl. CPC G06N 10/70; H03M 13/1148

(57) ABSTRACT

Methods involve performing a stabilizer measurement on a set of qubits to obtain a syndrome and, based on the syndrome, identifying errors in at least one of the qubits of the set of qubits using belief propagation based on a plurality of check node specific scaling factors. The method also involves, based on the identified error, correcting the identified error by applying at least one gate to the set of qubits or performing a classical operation.

### CROSS-REFERENCE TO RELATED APPLICATION

This application claims the benefit under 35 U.S.C. § 119 of U.S. application No. 63/627,690 filed 31 Jan. 2024 and entitled OPTIMISING BELIEF PROPAGATION DECODING FOR QEC CODES which is hereby incorporated herein by reference for all purposes.

### FIELD

The field is quantum error correction.

### BACKGROUND

Quantum computers have a significant physical error rate which can lead to erroneous results when executing a logical quantum circuit. This risk can be mitigated by using a quantum error correction (QEC) code to map the logical quantum circuit that a user wishes to run on k logical qubits to a physical quantum circuit with n physical qubits, in which n>k. Quantum information can be distributed across the additional qubits to provide redundancy for identifying and correcting errors that arise during computation. Unfortunately, existing QEC approaches continue to struggle with providing sufficient and computationally efficient correction.

### SUMMARY

In an aspect, a method is provided. The method involves obtaining a syndrome based on a stabilizer measurement performed on a set of qubits, wherein the set of qubits is encoded based on a code that is representable as a set of variable nodes and a set of check nodes, wherein selected check nodes are coupled to selected variable nodes. The method also involves, based on the syndrome, identifying errors in at least one of the qubits of the set of qubits using belief propagation based on a plurality of check node specific scaling factors αᵢ, wherein an i^{th} scaling factor αᵢ in the plurality of check node specific scaling factors is associated with an i^{th} check node in the set of check nodes.

The method may also involve, based on the identified error, correcting the identified error by applying at least one gate to the set of qubits or performing a classical operation.

The check node specific scaling factors αᵢ may be based on a number of variable nodes connected to the i^{th} check node.

Using belief propagation may involve using scaled minimum sum algorithm (MSA) belief propagation. The plurality of check node specific scaling factors may be selected to reduce a difference between messages determined at one or more check nodes using sum-product algorithm (SPA) and using scaled MSA with the plurality of check node specific scaling factors. The check node specific scaling factors αᵢ in each iteration of the belief propagation may depend on an iteration number. The check node specific scaling factors αᵢ may be determined as α=1−2^{-β}^{ᵢ}^{l}, wherein βᵢ is a constant associated with the i^{th} check node and l is an integer indicating the iteration number.

The code may be a quantum low density parity check (QLDPC) code or a quantum low density generator matrix (QLDGM) code.

The method may also involve selecting the plurality of check node specific scaling factors αᵢ based on a check nodes degree distribution of the code and a physical error rate of the set of qubits. Selecting the plurality of check node specific scaling factors based on the check nodes degree distribution of the code and the physical error rate of the set of qubits may involve sending a request, the request comprising an indication of the check nodes degree distribution and the physical error rate, and receiving, in response, an indication of the plurality of check node specific scaling factors. Selecting the plurality of check node specific scaling factors based on the check nodes degree distribution of the code and the physical error rate of the set of qubits may involve retrieving, from a look-up table, the plurality of check node specific scaling factors based on the check nodes degree distribution and the physical error rate.

The code may be selected from a set of quantum error correction codes that are representable as the set of variable nodes and the set of check nodes, wherein the selected check nodes are coupled to the selected variable nodes.

In an aspect, a computer readable medium is provided. The computer readable medium includes stored computer executable instructions that, when executed by at least one processor of a system, will cause the system to: obtain a syndrome based on a stabilizer measurement performed on a set of qubits, wherein the set of qubits is encoded based on a code that is representable as a set of variable nodes and a set of check nodes, wherein selected check nodes are coupled to selected variable nodes; and based on the syndrome, identify errors in at least one of the qubits of the set of qubits using belief propagation based on a plurality of check node specific scaling factors αᵢ, wherein an i^{th} scaling factor αᵢ in the plurality of check node specific scaling factors is associated with an i^{th} check node in the set of check nodes.

The system may be further caused to, based on the identified error, correct the identified error by applying at least one gate to the set of qubits or performing a classical operation. The check node specific scaling factors αᵢ may be based on a number of variable nodes connected to the i^{th} check node. Using belief propagation may involve using scaled minimum sum algorithm (MSA) belief propagation.

In an aspect, a quantum device is provided. The quantum device includes at least one processor and at least one process-readable memory coupled to the at least one processor. The at least one process-readable memory stores processor-executable instructions that, when executed by the at least one processor, will cause the quantum device to: obtain a syndrome based on a stabilizer measurement performed on a set of qubits, wherein the set of qubits is encoded based on a code that is representable as a set of variable nodes and a set of check nodes, wherein selected check nodes are coupled to selected variable nodes; and, based on the syndrome, identify errors in at least one of the qubits of the set of qubits using belief propagation based on a plurality of check node specific scaling factors αᵢ, wherein an i^{th} scaling factor αᵢ in the plurality of check node specific scaling factors is associated with an i^{th} check node in the set of check nodes.

The quantum device may be further caused to, based on the identified error, correct the identified error by applying at least one gate to the set of qubits or performing a classical operation. The check node specific scaling factors αᵢ may be based on a number of variable nodes connected to the i^{th} check node. Using belief propagation may involve using scaled minimum sum algorithm (MSA) belief propagation.

In an aspect, a method is provided. The method involves performing a stabilizer measurement on a set of qubits to obtain a syndrome, in which the set of qubits is encoded based on a code that is representable as a set of variable nodes and a set of check nodes. Selected check nodes are coupled to selected variable nodes. The method also involves, based on the syndrome, identifying errors in at least one of the qubits of the set of qubits using scaled MSA belief propagation. At least one MSA scaling factor α is selected to reduce a difference between messages determined at one or more check nodes using SPA and using scaled MSA with the at least one scaling factor α. The method also involves, based on the identified error, correcting the identified error by applying at least one gate to the set of qubits or performing a classical operation.

The at least one MSA scaling factor α may include a plurality of check node specific scaling factors αᵢ, in which an i^{th} scaling factor αᵢ is associated with an i^{th} check node. The check node specific scaling factors αᵢ may be determined based on a number of variable nodes connected to the i^{th} check node. The check node specific scaling factors; in each iteration of the scaled MSA belief propagation may depend on an iteration number. The check node specific scaling factors αᵢ may be determined as α=1−2^{-β}^{ᵢ}^{l}, in which βᵢ is a constant associated with the i^{th} check node and l is an integer indicating the iteration number.

The at least one scaling factor α may depend on an iteration number/of the scaled MSA belief propagation. The at least one scaling factor α may be determined as α=1−2^{-βl}, in which β is a constant.

The code may be a low density code, such as an LDPC code or a LDGM code.

The method may also involve selecting at least one MSA scaling factor based on a check nodes degree distribution of the code and a physical error rate of the set of qubits.

Selecting the at least one MSA scaling factor based on the check nodes degree distribution of the code and the physical error rate of the set of qubits may involve sending a request and receiving, in response, an indication of the at least one MSA scaling factor. The request may include an indication of the check nodes degree distribution and the physical error rate.

Selecting at least one MSA scaling factor based on the check nodes degree distribution of the code and the physical error rate of the set of qubits may involve retrieving, from a look-up table, the at least one MSA scaling factor based on the check nodes degree distribution and the physical error rate.

The code may be selected from a set of quantum error correction codes that are representable as the set of variable nodes and the set of check nodes, wherein the selected check nodes are coupled to the selected variable nodes.

In another aspect, a method is provided. The method involves performing a stabilizer measurement on a set of qubits to obtain a syndrome, in which the set of qubits is encoded based on a code that is representable as a set of variable nodes and a set of check nodes. Selected check nodes are coupled to selected variable nodes. The method also involves, based on the obtained syndrome, identifying an error in a state of one or more qubits of the set of qubits by iteratively performing the following steps L times, wherein L is an integer that is greater than 1: for each check node, determining syndrome log-likelihood ratios (LLRs) for each coupled variable node, and for each variable node, determining error LLRs for each coupled check node based on the syndrome LLRs, a physical error rate of the set of qubits, and a channel model. The error is identified in the one or more qubits in the set of qubits based on the error LLRs associated with a final iteration. Determining the syndrome LLRs involves, in a first iteration, determining the syndrome LLRs based on the obtained syndrome and, in each other iteration, updating the syndrome LLRs by inputting at least one of the error LLRs from a previous iteration to a scaled minimum sum algorithm (MSA) with at least one scaling factor. The at least one scaling factor is selected to reduce a difference between LLRs determined at one or more check nodes using a sum-product algorithm and using the scaled minimum sum algorithm with the at least one scaling factor. The method also involves, based on the identified error, applying at least one gate to the set of qubits to correct the identified error.

In another aspect, a method is provided. The method involves performing a stabilizer measurement on a set of qubits to obtain a syndrome, in which the set of qubits is encoded based on a quantum error correction code that is representable as a set of variable nodes and a set of check nodes. Selected check nodes are coupled to selected variable nodes. The method also involves, based on the syndrome, identifying errors in at least one of the qubits of the set of qubits using belief propagation based on a scaling factor that varies among the check nodes. The belief propagation may be MSA belief propagation. The method also involves, based on the identified error, correcting the identified error by applying at least one gate to the set of qubits or performing a classical operation.

The scaling factor may vary among the check nodes based on the number of connections between a particular check node and the variable nodes.

In another aspect, a processor configured to perform any of the foregoing methods is provided.

In another aspect, computer readable medium is provided. The computer readable medium includes stored computer executable instructions for performing any of the foregoing methods.

In another aspect, a quantum computer is provided. The quantum computer includes at least one processor and at least one process-readable memory coupled to the at least one processor. The at least one process-readable memory has stored thereon processor-executable instructions for performing any of the foregoing methods.

The foregoing and other objects, features, and advantages of the disclosed technology will become more apparent from the following detailed description, which proceeds with reference to the accompanying figures.

### BRIEF DESCRIPTION OF THE DRAWINGS

FIG. 1 is a flowchart illustrating iterative belief propagation decoding between check nodes and variable nodes, according to disclosed examples.

FIG. 2 illustrates a Tanner graph representation of a quantum error correction code.

FIG. 3 is a representative flowchart of an example quantum error correction method.

FIG. 4 illustrates an exemplary system in which quantum error correction may be performed on quantum circuits.

FIG. 5 illustrates an exemplary computing environment in which the disclosed technology may be implemented.

FIGS. 6-7 are graphs of logical error rate with respect to physical error rate achieved when decoding quantum low density parity check codes (QLDPC) using belief propagation.

FIG. 8 illustrates a representative flowchart of a method that can be used with various belief propagation approaches.

### DETAILED DESCRIPTION

### General Considerations

As used in this application and in the claims, the singular forms “a,” “an,” and “the” include the plural forms unless the context clearly dictates otherwise. Additionally, the term “includes” means “comprises.” Further, the term “coupled” does not exclude the presence of intermediate elements between the coupled items.

The systems, apparatus, and methods described herein should not be construed as limiting in any way. Instead, the present disclosure is directed toward all novel and non-obvious features and aspects of the various disclosed embodiments, alone and in various combinations and sub-combinations with one another. The disclosed systems, methods, and apparatus are not limited to any specific aspect or feature or combinations thereof, nor do the disclosed systems, methods, and apparatus require that any one or more specific advantages be present, or problems be solved. Any theories of operation are to facilitate explanation, but the disclosed systems, methods, and apparatus are not limited to such theories of operation.

Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed systems, methods, and apparatus can be used in conjunction with other systems, methods, and apparatus. Additionally, the description sometimes uses terms like “produce” and “provide” to describe the disclosed methods. These terms are high-level abstractions of the actual operations that are performed. The actual operations that correspond to these terms will vary depending on the particular implementation and are readily discernible by one of ordinary skill in the art.

In some examples, values, procedures, or apparatus' are referred to as “lowest”, “best”, “minimum,” or the like. It will be appreciated that such descriptions are intended to indicate that a selection among many used functional alternatives can be made, and such selections need not be better, smaller, or otherwise preferable to other selections.

The disclosed quantum error correction methods and apparatus can be applied to systems based on a variety of physical implementations of qubits such as those based on trapped ions, cold atoms, Josephson junction devices, solid state spin, Majorana fermions, photon polarization, luminescent defects (e.g. in silicon, silicon carbide or diamond), among others.

### QEC Overview

When a physical circuit mapped to by a QEC code is executed, QEC is often carried out by first performing a stabilizer measurement on one or more qubits in the physical circuit to obtain a syndrome, i.e., the measurement result. A stabilizer measurement is a measurement that extracts information from a quantum state without changing the state. Next, a decoder processes the syndrome to identify any error(s) that occurred (i.e., what error and which qubit(s) the error affected) and to determine a recovery operation to be performed to correct the error. A recovery operation can then be performed based on the identified error(s), e.g., an additional physical gate can be implemented to correct the error. Alternatively, the quantum state can be measured, and errors can be corrected in the measured state.

In general, there are two types of error that can occur in quantum computers: X errors (bit-flips) and Z errors (phase-flips). The co-occurrence of an X error and a Z error on the same qubit at the same time may be referred to as a Y error. For a particular type of QEC code, called a CSS (Calderbank-Shor-Steane) code, the above stabilizer measurement, syndrome decoding, and recovery operation can be performed separately for X errors and Z errors, using a Z code to correct X errors and an X code to correct Z errors. QEC codes for correcting X errors are called Z codes because the stabilizer measurements for a Z code involve Pauli-Z gates while QEC codes for correcting Z errors are called X codes because the stabilizer measurements for an X code involve Pauli-X gates. For non-CSS codes, the above three steps can be performed jointly for X and Z errors using a single QEC code.

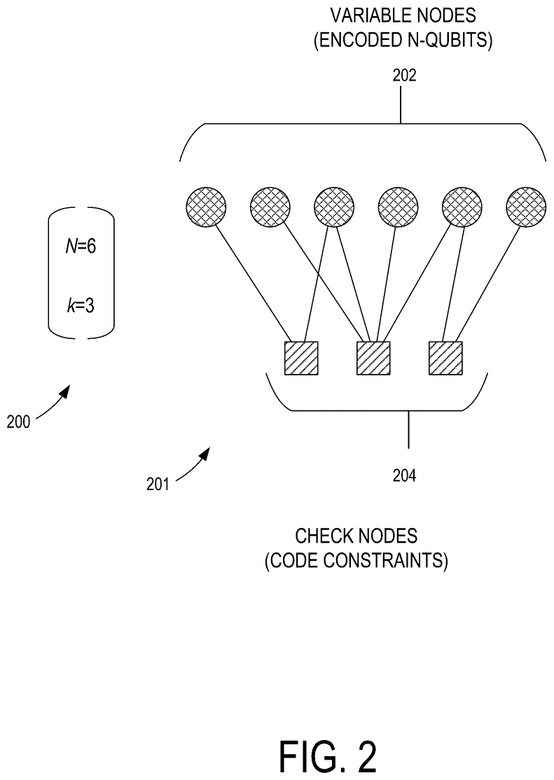

QEC can directly impact the performance of a quantum circuit. For example, if errors cannot be corrected, the circuit will provide erroneous results. Based on recent advances, low density codes such as Quantum Low Density Parity Check Codes (QLDPC) and Quantum Low Density Generator Matrix Codes (QLDGM) appear to be suitable candidates for high-connectivity quantum computers such as quantum computer based on optically-addressable quantum systems. However, for a given QEC code to perform well, the associated decoder also needs to perform well, as the decoder uses information provided by the syndrome to identify errors and suggest recovery operations. Belief propagation is a well-established decoding method for classical low density codes and has also been shown to be effective for quantum low density codes, i.e., for QEC codes with a sparse Tanner graph. Belief propagation is a message passing algorithm for decoding based on a code's Tanner graph. A Tanner graph has variable nodes and check nodes, which respectively represent the columns and rows of a parity check matrix defining the code. Each variable node is connected to one or more check nodes (e.g., two or more check nodes) by respective edges. For example, FIG. 2 shows an example Tanner graph representation 201 having a set 202 of six variable nodes and a set 204 of three check nodes. The Tanner graph representation is associated with a code with characteristics 200 specifying that the code has N=6 physical qubits and k=3 logical qubits.

Belief propagation typically involves repeating a series of steps over a number of iterations. For example, first, check nodes determine log-likelihood ratios (LLRs) of bits in the syndrome being equal to one (indicating that an error has occurred) versus bits in the syndrome being equal to zero (indicating that no error has occurred), LLR_{c}_{_{i→v}}ⱼ. In the first iteration, these LLRs indicate which bits in the measured syndrome (e.g., obtained from stabilizer measurements) are equal to one. That is, in the first iteration these LLRs may be either the logarithm of zero or the logarithm of infinity (in practice, a small number may be used in place of zero and a large number may be used in place of infinity). From the second iteration onwards, this is a prediction of which bits in the syndrome would be equal to one based on the qubit LLRs provided by the variable node at the end of the previous iteration. The check nodes compute LLR_{c}_{ᵢ}_{→v}_{ⱼ} (called the syndrome LLRs here for convenience) using a check node update rule. Second, check nodes send the syndrome LLRs to the variable nodes. Third, variable nodes determine LLRs of an error affecting particular qubits, LLRᵥ_{ⱼ}_{→c}_{ᵢ}, based on a variable node update rule, an assumed model of the quantum channel (also referred to as a channel model), and the syndrome LLRs received from check nodes. The LLRs determined by the variable nodes may be referred to as error LLRs. Next, variable nodes send the error LLRs to the check nodes. In some implementations of belief propagation, the check nodes and variable nodes may compute log-likelihoods or likelihoods instead of LLRs. As such, it will be appreciated that methods described herein as involving LLRs may be adapted to use log-likelihoods, likelihoods, or other equivalents. More generally, the values calculated by the check nodes and variable nodes may be referred to as messages, e.g., the messages determined at a check node or the messages determined at a variable node.

In iterative decoding processes, the information passed between the check nodes and the variable nodes is typically extrinsic, i.e., when a node passes a message to another node, it uses information from all other connected nodes to compose the message, but not information provided by the message recipient. Also, the formulation of the variable and check node update rules can depend on the algorithm that is used to implement belief propagation. Example algorithms include the sum-product algorithm (SPA) and the minimum sum algorithm (MSA). For example, the syndrome LLRs determined by check nodes using the MSA are based on at least one scaling factor in addition to the error LLRs. Various quantum channel models can be used, such as the binary erasure channel (BEC), the binary symmetric channel (BSC), the quaternary channel, quantum Pauli channel etc.

Particular issues can arise when decoding QEC codes using belief propagation. For example, QEC codes can have problematic loops, which reduces the performance of belief propagation decoding. Loops are particularly harmful for QEC codes because degeneracy, a strictly quantum phenomenon, causes a new type of trapping set, known as a split belief, which can further deteriorate the performance of belief propagation decoding. One way of addressing this involves patching belief propagation decoders with post-processing strategies. However, this can significantly increase decoding complexity. Another way of improving performance is through algorithm selection. For example, the SPA algorithm offers the best performance, but its complexity (since it requires calculating an inverse tanh) makes it challenging to implement at runtime sufficiently quickly that error correction can be performed before qubits decohere. MSA is less complex but has reduced performance. A further alternative is a refinement to MSA, called scaled MSA.

In general, check nodes using MSA are overly optimistic compared to SPA, i.e. they provide extrinsic LLR values that are larger than would be provided by MSA. Scaled MSA compensates for this by scaling the LLR values computed by check nodes according to MSA by a scaling factor, α, such that the LLR is given by:

$${LLR}_{{c}_{i} \to {v}_{j}} = α ( {\prod }_{k}^{{d}_{c} - 1} sign ( {LLR}_{{v}_{k}} ) ) \cdot min \{ {LLR}_{{v}_{k}} \} \qquad ( 1 )$$

in which k∈∂cᵢ\vⱼ, i.e. the LLR calculated by check node c; to be sent to variable node vⱼ is based on the LLRs received from all of the variable nodes connected to the check node, LLRᵥ_{ₓ}, except for the variable node vⱼ. d_{c} is the number of variable nodes connected to the check node and sign (x) returns the sign of the variable x.

Setting the scaling factor equal to a constant value in the range between 0 and 1 (e.g., the same value for all iterations of the decoder and all check nodes) can improve decoder performance if the value of a is selected appropriately. Also, decoder performance can improve when the value of α varies between different iterations according to

$$α = 1 - {2}^{- l} , \qquad ( 2 )$$

in which l is the number of the current iteration in belief propagation decoding.

Optimal values of the scaling factor can be found manually (e.g., by using Monte Carlo simulations to evaluate performance for different values of α) or using neural networks trained on a subset of all possible error patterns that could occur to map error patterns to syndrome measurements. However, Monte Carlo simulations are time consuming to run and the approaches using neural networks require large amounts of training data, which requires significant resources to obtain. Also, it is not guaranteed that neural networks will find the optimal solution. Because the optimal value of α is expected to vary for different codes and for hardware with different physical error rates, it can be expected that fault tolerant quantum computers will use large libraries of QEC codes that are appropriate for different circuits and different hardware. To achieve optimal performance, each of the QEC codes in these large libraries of QEC codes will require an optimized decoder. An efficient method of optimizing the value of α for scaled MSA belief propagation for different QEC codes is lacking.

### Scaled MSA Belief Propagation

The disclosed methods and apparatus involve improved quantum error correction (QEC) techniques. More particularly, some methods and apparatus relate to optimizing the scaling factor for scaled-MSA (minimum-sum algorithm) belief propagation decoding by minimizing a cost function that is based on a comparison of the extrinsic information determined at check nodes using scaled MSA and the extrinsic information determined at check nodes using SPA (sum-product algorithm). The terms scaling factor and scaling parameter may be used interchangeably herein.

Some methods and apparatus relate to performing belief propagation decoding using check-node specific scaling parameters (dynamic or static).

In some examples, described approaches can be used to determine an optimized constant value of α, a parameter, β, that characterizes a dynamic scaling factor that depends both on β and l, the iteration number, (e.g. α=1−2−^{βl}), and/or check node-specific values of α or β. Using the disclosed methods and apparatus can result in improved performance of the belief propagation algorithm without increasing complexity at runtime. In addition, proposed approaches for optimizing the scaling factor values can be quicker than existing approaches using Monte Carlo simulations or neural networks, allowing the parameter space of QEC codes and values of a to be explored more quickly.

Representative examples can be described in relation to EXIT charts, which are used to evaluate the convergence behavior of iterative decoding schemes like belief propagation decoding. An EXIT chart is a graph upon which two lines are plotted: one line for check nodes and the other for variable nodes. Each line represents the extrinsic information at the nodes in question (I_{E,c} for check nodes and I_{E,v} for variable nodes) against the a priori information at those nodes (I_{A,c} for check nodes and I_{A,v} for variable nodes) during belief propagation decoding.

A typical use of this analysis for classical codes involves visualizing these curves for the same decoder used for codes with different degree distributions p and 2, and selecting the code which minimizes the gap between the curves while ensuring the curves do not intersect before reaching the (1,1) point. Codes with curves that do not intersect before reaching the (1,1) point will have decoding convergence.

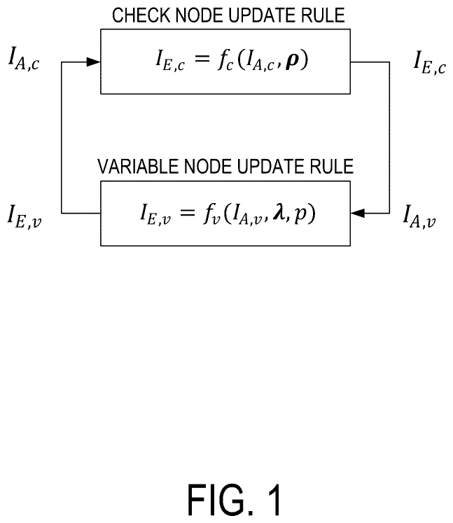

The definition of the values I_{E,c}, I_{A,c} etc. can be understood with reference to FIG. 1. As shown, I_{A,c} is the check nodes' a priori information, i.e., for each variable node that the check node is to send information to, the a priori information is the information that the check node received in the previous iteration from all of the other variable nodes that it is connected to. I_{A,v} is the variable nodes' a priori information, i.e., for each check node the variable node is to send information to, the a priori information is the information that the variable node received in the previous iteration from all of the other check nodes that it is connected to. I_{E,c} and I_{E,v} are the extrinsic information of the check nodes and the variable nodes respectively. Here, extrinsic information means the mutual information obtained after processing at the respective node, i.e., the information obtained as a result of applying the update rule. fᵥ and f_{c} are functions based on the variable node and check node update rules. fᵥ and f_{c} indicate the mutual information that is gained as a result of applying the update rules during belief propagation decoding. f_{c} depends on the check nodes' a priori information and the check nodes' degree distributions ρ, which is a vector indicating how many check nodes are connected to 0, 1, 2, 3, etc. variable nodes. fᵥ depends on the variable nodes' a priori information, the physical error rate, p, (i.e., how likely it is that a hardware error will occur), and the variable nodes' degree distributions λ, which is a vector indicating how many variable nodes are connected to 0, 1, 2, 3, etc. check nodes. Because belief propagation is iterative, the check nodes' extrinsic information I_{E,c} becomes the variable nodes' apriori information I_{A,v}. Similarly, the variable nodes' extrinsic information I_{E,v} becomes the check nodes' apriori information I_{A,c}.

As mentioned above, scaled-MSA can be understood as a simplification of SPA, in which the LLRs calculated at the check nodes are scaled by a scaling factor α to mitigate the tendency of MSA to overestimate the check nodes' LLRs. In representative examples herein, optimal values of the scaling parameter, α, are found by finding the value(s) of a that minimize the square error between the extrinsic information provided by check nodes in SPA, I_{SPA,E,c} and the extrinsic information provided by check nodes in scaled-MSA, e.g., the value of α that minimizes

$$ε ( α ) = {\int }_{{I}_{A , c}} {[ {I}_{SPA , E , c} - {I}_{MSA , E , c} ]}^{2} {dI}_{A , c} \qquad ( 3 )$$

Since I_{E,c}=f_{c} (I_{A,c}, φ for SPA and I_{E,c}=f_{c} (I_{A,c}, ρ, α) for scaled MSA, this cost function can also be expressed as:

$$ε ( α ) = {\int }_{{I}_{A , c}} {[ {f}_{SPA} ( {I}_{A , c} , ρ ) - {f}_{MSA} ( {I}_{A , c} , ρ , α ) ]}^{2} {dI}_{A , c} . \qquad ( 4 )$$

This cost function can be minimized using various known minimization techniques, such as gradient descent algorithms (e.g. gradient descent, stochastic gradient descent, adaptive gradient descent, etc.). In some examples, the cost function may be minimized using a machine-learning process or algorithm.

While performing this minimization, the value of ρ, the check nodes degree distribution of the QEC code to be decoded, is kept constant. This means that the value of α determined through this analysis is optimized for QEC codes with check nodes degree distribution equal to ρ. That is, the value of α is degree distribution-specific, but not code specific since different QEC codes may have the same degree distribution. This analysis also assumes a particular physical error rate, p (e.g., indicative of a probability of X and/or Z errors occurring on a particular quantum computer). As such, references to a scaling factor for a particular QEC code herein may refer to a scaling factor that is specific to a particular check nodes degree distribution and physical error rate.

The form of f_{SPA} and f_{MSA} can depend on the channel model being used. In general, for SPA:

$${I}_{SPA , E , c} = {f}_{SPA} ( {I}_{A , c} , ρ ) = {{\sum }^{max i}}_{i} {ρ}_{i} {I}_{A , c} ( {LLR}_{SPA , {c}_{i} \to {v}_{j}} ) , \qquad ( 5 )$$

where the value of I_{A,c} is determined based on the received error LLRs, LLR_{SPA,c}_{ᵢ}_{→v}_{ⱼ}.

More specifically,

$${LLR}_{SPA , {c}_{i} \to {v}_{j}} = {\prod }_{k}^{{d}_{c} - 1} {LLR}_{{v}_{k}}$$

in which k∈∂cᵢ\vⱼ. For MSA,

$${I}_{MSA , E , c} = {f}_{MSA} ( {I}_{A , c} , ρ , α ) = {{\sum }^{max i}}_{i} {ρ}_{i} {I}_{A , c} ( {LLR}_{MSA , {c}_{i} \to {v}_{j}} ) \qquad ( 6 )$$

where the value of I_{A,c} is determined based on the received error LLRs LLR_{MSA,c}_{ᵢ}_{→v}_{ⱼ}; More specifically,

$${LLR}_{MSA , {c}_{i} \to {v}_{j}} = α ( {\prod }_{k}^{{d}_{c} - 1} sign ( {LLR}_{{v}_{k}} ) ) \cdot min \{ {LLR}_{{v}_{k}} \}$$

in which k∈∂cᵢ\vⱼ. Substituting Equations (5) and (6) into Equation (4) gives

$$ε ( α ) = {\int }_{{I}_{A , c}} {[ {{\sum }^{max i}}_{i} {ρ}_{i} {I}_{A , c} ( {LLR}_{SPA , {c}_{i} \to {v}_{j}} ) - {{\sum }^{max i}}_{i} {ρ}_{i} {I}_{A , c} ( {LLR}_{MSA , {c}_{i} \to {v}_{j}} ) ]}^{2} {dI}_{A , c} . \qquad ( 7 )$$

This may equivalently be expressed as:

$$ε ( α ) = {\int }_{{I}_{A , c}} {{\sum }^{max i}}_{i} {{ρ}_{i} [ {I}_{A , c} ( {LLR}_{SPA , {c}_{i} \to {v}_{j}} ) - {I}_{A , c} ( {LLR}_{MSA , {c}_{i} \to {v}_{j}} ) ]}^{2} {dI}_{A , c} . \qquad ( 8 )$$

The form of I_{A,c} depends on the channel model. For example, for the binary erasure channel, I_{A,c}(q)=1−q, in which

$$q = \frac{1}{1 + {e}^{LLR}} , \qquad ( 9 )$$

in which the LLR is LLR_{MSA,c}_{ᵢ}_{→v}_{ⱼ} for MSA and LLR is LLR_{SPA,c}_{ᵢ}_{→v}_{ⱼ} for SPA. In another example, for the binary symmetric channel I_{A,c}(q)=1−H₂(q), where q is as given in Equation (9) and H₂(q) is the binary entropy of q:

$${H}_{2} ( q ) = - q {log}_{2} q - ( 1 - q ) {log}_{2} ( 1 - q ) . \qquad ( 10 )$$

Although there are various channel models that can be used, the binary symmetric channel model is a better approximation of the quantum channel than the binary erasure channel.

As CSS codes have separate codes for correcting X and Z errors, the optimal value of α for a particular X code may be different to the optimal value of α for the Z code that is to be used with the X code. Thus, for CSS codes, the analysis described above can be performed independently for X and Z codes. Non-CSS codes use a single code (i.e., a code defined by a single parity check matrix (PCM)) for correcting both X and Z errors. As such, for non-CSS codes, the analysis described above can be performed once to obtain a single value of α or β. There are also differences between belief propagation decoding for CSS and non-CSS codes. For example, non-CSS codes can be decoded using binary belief propagation (also referred to as decoding over GF(2)) or using quaternary belief propagation (also referred to as decoding over GF(4)). Binary and quaternary belief propagation are known techniques. Low density codes (e.g., LDPC or LDGM codes) can be CSS or non-CSS.

In some examples, the value of α may be a single value, i.e., one value of α may be used for all iterations and check nodes of belief propagation decoding. In some examples, it is possible to determine optimal values of α that are specific to a particular iteration and/or check node in belief propagation decoding.

In some examples, a dynamic scaling factor can be implemented, in which the scaling factor varies depending on iteration according to a particular (e.g. pre-defined) relationship. This relationship may be characterized in terms of a parameter β (or more than one parameter) that can be optimized using the techniques described herein. In some examples, the scaling factor may depend on the parameter β and the iteration number such that the scaling factor monotonically increases towards 1 as the iteration number increases. One example of such a relationship for the scaling factor can be expressed as

$$α = 1 - {2}^{- β l} , \qquad ( 11 )$$

in which l is the iteration number. β may be optimized by minimizing the cost function given in Equation (4) above, for example. Using this expression for a can result in more stable error correction performance (e.g., performance that is less sensitive to variations in the physical error rate) than using a constant value of α, without unduly increasing runtime complexity.

The performance of belief propagation decoding can be improved by selecting the scaling parameter (dynamic or static) for each check node e.g. having check-node specific scaling parameters. The scaling parameter for a particular check node may be selected based on its degree, e.g., based on how many variable nodes it is connected to. Examples in which a scaling parameter is selected for each check node based on degree can include examples in which identification of errors is performed using scaled MSA (such as described in more detail herein) as well as for other (disclosed or undisclosed) belief propagation based decoding methods that may be used in QEC. In some examples, the optimal value of the scaling parameter for check nodes with different degrees can be determined by performing the analysis above for “mock” codes with different uniform degree distributions. Here, a mock code may be a reference to a code that is being used for optimizing the scaling parameter, e.g., rather than for encoding a k-qubit data state. For example, the analysis above can be performed for a first mock code in which each check node is connected to one variable node, a second mock code in which each check node is connected to two variable nodes, a third mock code in which each check node is connected to three variable nodes, and a fourth mock code in which each check node is connected to fourth variable nodes, etc., to create a library of optimal values of the scaling parameter for different check node degrees. Then, during belief propagation, a different scaling parameter may be selected, from the library of optimal values, for each check node based on its degree.

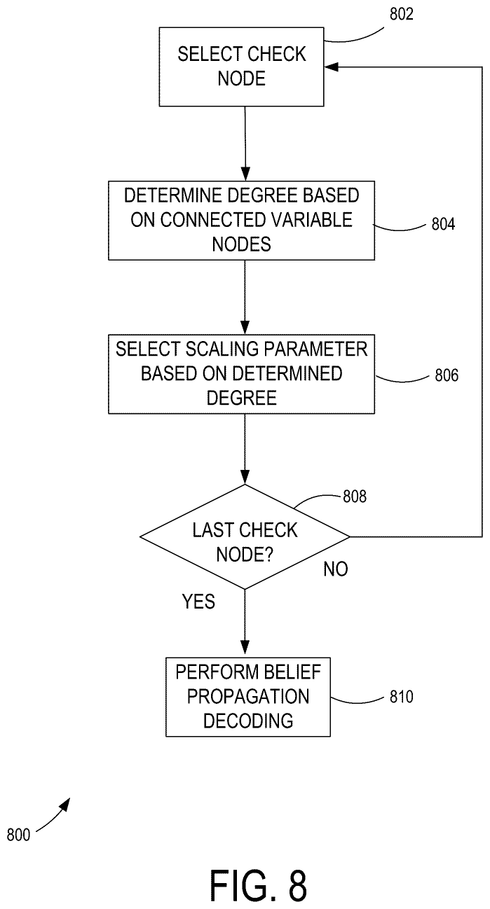

FIG. 8 shows an example method 800 of performing belief propagation decoding in which a scaling parameter can be used (and therefore be different between) for each check node based on the number of connected variable nodes. For a belief propagation based decoding of a k-qubit data state encoded using a QEC code with Tanner graph having variable nodes and check nodes, at 802, a check node can be selected (e.g. identified) from the check nodes associated with the QEC code.

At 804, the degree of the check node can be determined based on the number of variable nodes connected to the check node in the Tanner graph. The degree of a check node may be calculated at 804 (e.g., by using the approach using mock codes described above), retrieved from a memory or received from another entity (e.g. on request).

At 806, a scaling parameter can be selected and associated with the check node based on the determined degree, e.g., based on a look-up table.

At 808, a check can be performed as to whether all of the check nodes have been examined (i.e. the last check node has been examined). If more check nodes should be assigned scaling parameters, the process can return to check node selection at 802. In this way, a check-node specific scaling parameter may be assigned to each check node in the Tanner graph.

After the last check node has been examined and assigned a scaling parameter based on its degree, at 810, a belief propagation decoding process can be performed, e.g., any belief propagation approach described herein as well as other conventional or non-conventional belief propagation approaches. For example, 810 may be performed in accordance to 313 described below. In some examples, 810 may involve performing 312, 313 and 320.

In some examples, 810 may be performed by separately (e.g. by a different entity or at a later time) to 802-808. For example, a first entity may perform 802-808 to determine a respective scaling factor for each check node of a QEC code. A second entity may receive those scaling factors from the first entity and perform 810. The second entity may receive the respective scaling factor for each check node in response to a request to the first entity. The request may, for example, indicate the check nodes degrees and, optionally, a physical error rate.

In another example, 802-808 may be performed for each of the check nodes of a QEC code and the determined scaling factors may be stored in memory (e.g. in a look-up table). Those scaling factors may be retrieved from the memory in order to perform 810. The scaling factors may, for example, be retrieved from a look-up table, e.g., based on the check nodes degrees and, optionally, a physical error rate.

### Scaled MSA Based QEC

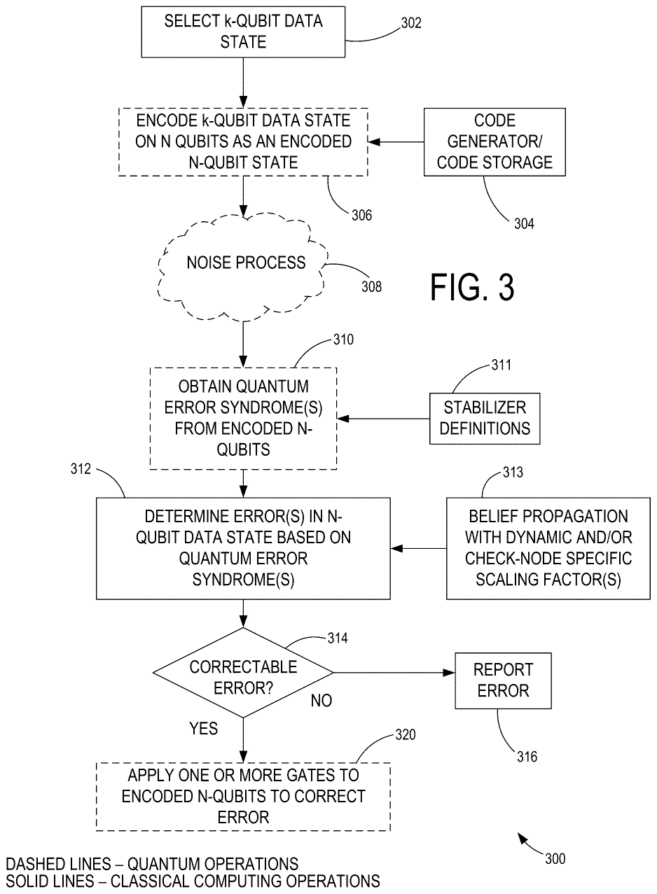

Referring to FIG. 3, a method 300 of quantum error correction includes selecting a k-qubit data state at 302. Selecting a k-qubit data state in 302 may involve receiving initial values of k logical qubits, e.g., from a user.

After the k-qubit state is selected, the k-qubit state is encoded on N physical qubits in 306. This may be referred to as state encoding. As discussed above, there are various physical qubit implementations, which may use, for example, photons, electrons, atomic nuclei, optical lattices, Josephson junctions, quantum dots, vibrational states, etc. In particular examples, the physical qubits may comprise spin qubits such as spin qubits associated with luminescent defects in semiconductor material e.g. T centres in silicon, defects in silicon carbide, NV defects in diamond etc. Physical qubits are prone to errors as reflected by the significant physical error rates of quantum computers.

Encoding the k-qubit state on N physical qubits involves mapping the values of k logical qubits specified by the data state selected at 302 to N physical qubits according to a particular QEC code, in which N>k. The particular QEC code may be selected from a set of QEC codes. The mapping from logical qubits to physical qubits for a particular QEC code may be retrieved from a memory or another entity e.g. from the code generator/code storage 304.

Thus, at 306, the selected k-qubit data state is encoded on N physical qubits as an encoded N-qubit state.

A noise process 308 can occur against the encoded N-qubit state in which the noise affects the N-qubit state causing various errors, such as bit-flips (X-errors) and/or phase-flips (Z-errors). A combination of a bit-flip and a phase-flip may be referred to as a Y-error.

At 310, a quantum error syndrome is obtained from the encoded N-qubits to extract information from the noise-affected N-qubit state without changing the quantum state. That is, one or more stabilizer measurements are performed on the N-qubits to obtain the quantum error syndrome. The measurement(s) to obtain the syndrome can be tailored according to stabilizer definitions 311, e.g., based on the encoded N-qubit state or, equivalently, the QEC code.

At 312, error(s) in the N-qubit state can be determined (identified) based on the obtained quantum error syndrome. The determination at 312 may involve, at 313, using scaled MSA belief propagation as described above to identify the error(s). An example implementation at 313 is described below. The scaling factor(s) may be static, dynamic and/or check-node specific scaling factor(s), or a combination thereof. In one example, a single, static scaling factor may be used for all iterations and check nodes in the belief propagation at 313. In another example, the scaling factor used for check-nodes of a particular degree may be static, whilst the check-nodes of a different degree may be dynamic (e.g. may vary according to Equation (11)). In a further example, a degree-specific, dynamic scaling factor may be used for each check node.

The scaling factor(s) may be determined using the approaches described above. In some examples, the scaling factor(s) may be selected to reduce a difference between messages (e.g. LLRs) determined at one or more check nodes using SPA and using scaled MSA with the scaling factor(s). The scaling factor(s) may be selected to reduce (e.g. minimize) a cost function that is based on a difference between the extrinsic information determined at check nodes using scaled MSA and the extrinsic information determined at check nodes using SPA, such as the cost function given in Equation (3) or the cost function given in Equation (4). It will be appreciated that Equations (3) and (4) are examples of suitable cost functions, and others may be used. For example, the square (exponent) in Equations (3) and (4) may be replaced by taking an absolute value. More generally, the scaling factor(s) may be selected by minimizing a difference between the extrinsic information determined at check nodes using scaled MSA and the extrinsic information determined at check nodes using SPA.

In some examples, the scaling factor(s) may be computed ahead of time and retrieved for use in belief propagation decoding at 313. As described above, the scaling factor(s) may be specific to (e.g. optimized for) a check nodes degree distribution and a physical error rate. In some examples, the method 300 may involve selecting the scaling factor(s) based on a check nodes degree distribution of the QEC code and a physical error rate of the qubits. Here, the physical error rate of the qubits may include the total rate at which various types of error occur e.g. gate, measurement and/or qubit errors. There are various ways in which the scaling factor(s) may be selected based on these properties. For example, an indication of the scaling factor(s) may be received (e.g. from another entity) in response to sending a request that indicates the check nodes degree distribution and the physical error rate. In another example, the scaling factor(s) may be retrieved from a look-up table that indexes scaling factor(s) based on check nodes degree distribution (or QEC code) and physical error rate. In some examples, the scaling factor(s) may already be assumed to be specific to a physical error rate. This may occur when, for example, the look-up table is specific to a particular quantum computer or quantum communication device with a known (or assumed) physical error rate.

At 314, a check can be performed as to whether the determined error is correctable. If it is not correctable, the error can be reported at 316 (e.g., so that some or all of the steps of the method 300 may be re-attempted). In some examples, reporting of the error at 316 may result in further iterations of belief propagation being performed. For example, belief propagation may continue until the errors are correctable unless, optionally, a maximum number of iterations has been reached.

If the error is correctable, at 320, at least one quantum gates can be applied to the encoded N-qubits to correct the error. In some examples, the error can be corrected using one or more classical computing operations, e.g., after the N-qubit state has been read out. For example, a classical bit-flip may be performed on a measurement value obtained after reading out the N-qubit state.

In some examples, the determined error comprises a matrix indicating which error(s) affected which qubits. This matrix may be referred to as an error matrix. Determining whether the error is correctable may involve multiplying the error matrix by the parity check matrix of the QEC code to obtain a result. If the result is equal to zero (or a zero vector), then the error is correctable. If the result is not equal to zero (e.g. one or more elements of the result are non-zero), then the error is not correctable.

In some embodiments, the method 300 may be used to perform quantum computation. It will be appreciated that, in such embodiments the purpose of correcting an errors determined in 312 might not be to return the N physical qubits to the N-qubit state encoded in 306. Rather, the N-qubit state may have evolved during the quantum computation (e.g. during execution of a logical quantum circuit), and the error correction may be intended to correct the N-qubit state to the state it would have been in after the quantum computation was performed if the error had not occurred.

In embodiments in which the method 300 is used to perform quantum computation, the method 300 may also involve selecting a logical quantum circuit to execute. For example, a logical quantum circuit may be received from a user, such as a user who supplied the k-qubit data state in 302. The logical quantum circuit includes one or more logical quantum gates to be implemented on the k logical qubits. The method 300 may also involve encoding the logical quantum circuit. This may be referred to as gate encoding. Encoding the logical quantum circuit involves mapping the logical quantum circuit to a physical quantum circuit that includes physical gate(s) to be implemented on the N physical qubits. That is, encoding the logical quantum circuit may involve mapping the one or more logical gates in the logical quantum circuit to one or more physical gates in the physical quantum circuit, in which the physical gates are to be implemented on the N physical qubits. The mapping from logical quantum gate(s) to physical quantum gate(s) for a particular QEC may be retrieved from a memory or another entity e.g. from the code generator/code storage 304. The physical gate(s) corresponding to a particular logical quantum gate may be referred to as a representation of that logical quantum gate.

The method 300 may also involve executing the physical quantum circuit. That is, the method 300 may involve causing the physical gate(s) in the physical quantum circuit to be performed on the N physical qubits, e.g., by sending instructions to cause the physical gate(s) to be implemented. The noise process 308 may occur before, after and/or during execution of the physical quantum circuit. The noise process 308 may comprise one or more of: a qubit error (e.g. qubit decoherence), a gate error and a measurement error.

In some embodiments, 308-320 may be performed one or more times during the execution of the physical quantum circuit. That is, multiple error correction cycles may be implemented during execution of the physical quantum circuit (e.g. using piecewise or pieceable fault tolerance). Thus, for example, the method may return to 308 after 320.

In some embodiments, the method 300 may be used to perform quantum communication or quantum networking. In such embodiments, the noise process 308 may occur during transmission, measurement and/or storage of the N-qubit state, for example. Steps 302 and 306 may, for example, be performed at a different entity to steps 310-320. For example, steps 302 and 306 may be performed at a transmitter and steps 310-320 may be performed by a receiver.

### Example Implementation at 313

An example implementation of belief propagation at 313 may involve performing iteratively performing a number of steps L times, in which L is an integer that is greater than 1. The steps involve, for each check node, determining syndrome log-likelihood ratios (LLRs) for each coupled (or connected) variable node and for each variable node, determining error LLRs for each coupled (or connected) check node based on the syndrome LLRs, a channel model and a physical error rate of the qubits. The physical error rate may be indicative of a probability of a qubit error, a gate error and/or a measurement error occurring on the qubits. The form of the physical error that is used may vary depending on the channel model. For example, when the channel model comprises the binary erasure channel, the erasure probability may be used. When the channel model comprises the quantum Pauli channel, a Pauli error probability of the qubits may be used. When the channel model comprises the binary symmetric channel, a transition probability for the qubits may be used.

In the first iteration, the syndrome LLRs are determined based on the syndrome obtained in 310. In each other iteration, the syndrome LLRs are updated by inputting at least one of the error LLRs from a previous iteration to a scaled MSA with the scaling factor(s) described above in respect of 312, in which the scaling factor(s) are selected to reduce a difference between LLRs determined at one or more check nodes using SPA and using the scaled MSA with the scaling factor(s). Returning to 312, the error is identified based on the error LLRs associated with a final iteration.

### Representative Computing Environments

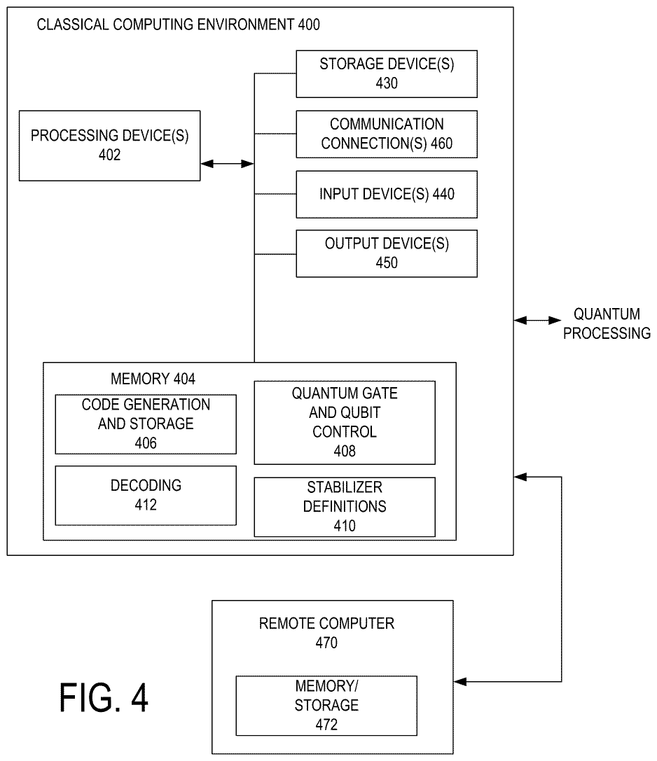

FIG. 4 shows a generalized example of a suitable classical computing environment 400 in which several of the described examples can be implemented. The computing environment 400 is not intended to suggest any limitation as to the scope of use or functionality of the disclosed technology, as the techniques and tools described herein can be implemented in diverse general-purpose or special-purpose environments that have computing hardware. It will be appreciated that some or all of the components of the computing environment 400 may be provided separately.

With reference to FIG. 4, the computing environment 400 includes at least, one processing device(s) 402 and (processor-readable) memory 404. The processing device(s) and memory 404 can be embodied, for example, in one or more PCs. The processing device(s) 402 (e.g., CPUs, microprocessor, etc.) executes computer-executable instructions (e.g. processor-executable instructions). In a multi-processing system, multiple processing devices execute computer-executable instructions to increase processing power. The memory 402 may be volatile memory (e.g., registers, cache, RAM, DRAM, SRAM), non-volatile memory (e.g., ROM, EEPROM, flash memory), or some combination of the two. The memory 402 can store computer-executable instructions 406 for generating and storing error correction codes that can be applied to quantum circuits, instructions 408 for controlling quantum gates and qubit encoding (including error correction gates that may be applied after encoding), instructions 410 that can include stabilizer definitions for obtaining syndrome measurements from encoded and error-affected qubits, and instructions for performing steps of quantum error correction techniques as described herein.

The computing environment 400 can have additional features. For example, the computing environment 400 includes storage 430, one or more input devices 440, one or more output devices 450, and one or more communication connections 460. An interconnection mechanism (not shown), such as a bus, controller, or network, interconnects the components of the computing environment 400. Typically, operating system software (not shown) provides an operating environment for other software executing in the computing environment 400, and coordinates activities of the components of the computing environment 400.

The input device(s) 440 can be a touch input device such as a keyboard, touchscreen, mouse, pen, trackball, a voice input device, a scanning device, or another device that provides input to the computing environment 400. The output device(s) 450 can be a display device (e.g., a computer monitor, laptop display, smartphone display, tablet display, netbook display, or touchscreen), printer, speaker, or another device that provides output from the computing environment 400. The computing environment 400 can also be coupled to or in communication with quantum processing components, including but not limited to a measurement device, a photonic circuit, a qubit controller that may include an optical pulse generator, a microwave pulse generator, a radio frequency pulse generator and/or electrical control means etc.

The communication connection(s) 460 enable communication over a communication medium to another computing entity, such as the remote computer 470. The communication medium conveys information such as computer-executable instructions or other data in a modulated data signal. A modulated data signal is a signal that has one or more of its characteristics set or changed in such a manner as to encode information in the signal. By way of example, and not limitation, communication media include wired or wireless techniques implemented with an electrical, optical, RF, infrared, acoustic, or other carrier.

As noted, the various methods, quantum encoding and decoding techniques, and quantum error correction techniques can be described in the general context of computer-readable instructions stored on one or more computer-readable media. Computer-readable media are any available media (e.g., memory or storage device) that can be accessed within or by a computing environment. Computer-readable media include tangible computer-readable memory or storage devices, such as memory 404 and/or storage 430, and do not include propagating carrier waves or signals per se (tangible computer-readable memory or storage devices do not include propagating carrier waves or signals per se).

Various embodiments of the methods disclosed herein can also be described in the general context of computer-executable instructions (such as those included in program modules) being executed in a computing environment by a processor. Generally, program modules include routines, programs, libraries, objects, classes, components, data structures, and so on, that perform particular tasks or implement particular abstract data types. The functionality of the program modules may be combined or split between program modules as desired in various embodiments. Computer-executable instructions for program modules may be executed within a local or distributed computing environment.

In some examples, classical steps associated with quantum error correction can be performed remotely by a remote computer 470 (e.g., a computer having a computing environment as described above with respect to FIG. 4), which also can store, e.g., code generation tables and instructions, decoding steps, etc., in one or more memory or storage devices 472 and can transmit error corrections (such as gate selection) to the computing environment 400. Still further, the remote computer 470 can store the high-level description in the memory or storage devices 472 and transmit the high-level description to the computing environment 400 for compilation and use with the processing device(s) 402 and/or other quantum processing components. In particular examples, the environment 400 can be a cloud computing environment, and/or the remote computer 470 can be part of a cloud computing environment.

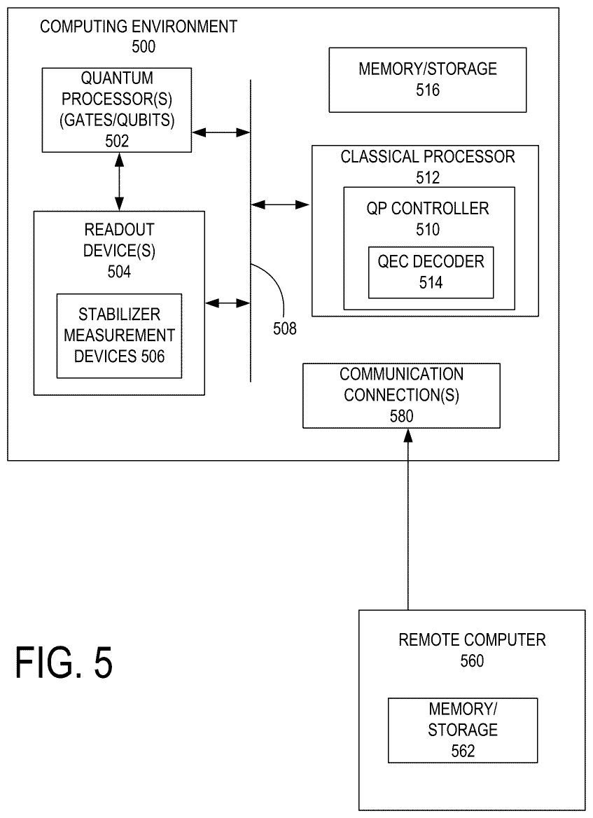

With reference to FIG. 5, an exemplary system for implementing the disclosed technology includes computing environment 500. In computing environment 500, quantum error correction techniques can be applied to selected quantum data states (including any of the quantum error correction techniques described herein), including the application of error corrections to data states processed by one or more quantum processing units such that the quantum processing unit(s) implement the error corrections or error corrections are applied post measurement.

The environment 500 includes one or more quantum processor(s) 502 and one or more measurement/readout device(s) 504 which can include stabilizer measurement device(s) 506 that can be used to obtain syndrome measurements. In some embodiments, the one or more measurement/readout device(s) 504 may be partially or wholly part of (e.g. integral to) the quantum processor(s) 502.

The quantum processor(s) 502 can execute quantum circuits that include a series of quantum gates configured to perform quantum operations, such as encoding, processing a selected quantum data state, and applying error corrections. In some examples, the execution of a quantum circuit may be distributed over a plurality of quantum processor(s). Thus, portions of the quantum processing can be performed at and/or received from a remote location. The quantum processor(s) 502 can be one or more of, but are not limited to, a superconducting quantum computer, an ion trap quantum computer, solid state spin (e.g. silicon spin) quantum computer and/or a topological quantum architecture. The quantum circuits can be sent into (or otherwise applied to) the quantum processing unit(s) via control lines 508 at the control of quantum processor controller 510. The quantum processor controller (QP controller) 510 can operate in conjunction with a classical processor 512 (e.g., having an architecture as described above with respect to FIG. 4) to implement the desired quantum computing process and quantum error correction.

In the illustrated example, the QP controller 510 further implements the desired quantum computing process via one or more QP decoders 514 that can be used to determine errors in an N-qubit data state based on obtained syndromes. The QP controller 510 may, for example, implement some or all of the method 300 or the method 800. For instance, in one example, the quantum controller 510 facilitates quantum error correction implementation of a quantum circuit by sending instructions to one or more memories that transmit gate instructions (e.g., via pulse sequences or other control signals) to the quantum processors 502 for implementation of qubit data state corrections. In other examples, the QP controller(s) 510 can operate to determine and/or apply corrections after measurement of a processed data state with the readout device(s) 504, e.g., by further interacting with readout devices 504 to help control and implement the desired quantum computing process (e.g., by reading or measuring out data results from the quantum processor once available, etc.

QEC is the process of selecting suitable encoding characteristics for a selected quantum data state, identifying errors that can occur after encoding and optionally further processing the encoded data state, and correcting (the quantum state or post-measurement) or reporting the errors, which can include quantum error correction approaches as disclosed herein. Selected steps (e.g. from the method 300 or the method 800) can be performed by the QEC decoder 514 using the classical processor 512 (e.g., as shown in FIG. 4) of the environment 500 which can access code maps and iterative decoding routines from memory or storage devices 516 and stores the resulting corrected measured states in the memory or storage devices 516. In other examples, one or more quantum error correction steps (e.g. from the method 300 or the method 800) can be performed remotely by a remote computer 560 (e.g., a computer having a computing environment as described above with respect to FIG. 4) which determine and store errors in one or more memory or storage devices 562 and transmit error information and corrections to the computing environment 500 for implementation by the quantum processor 502. In general, the remote computer 560 communicates with the QP controller(s) 510 via communication connections 580.

### Experimental Results

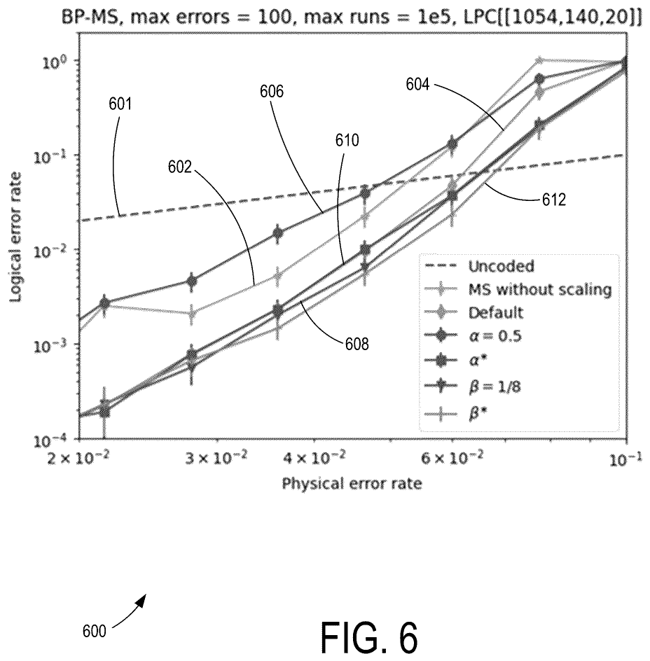

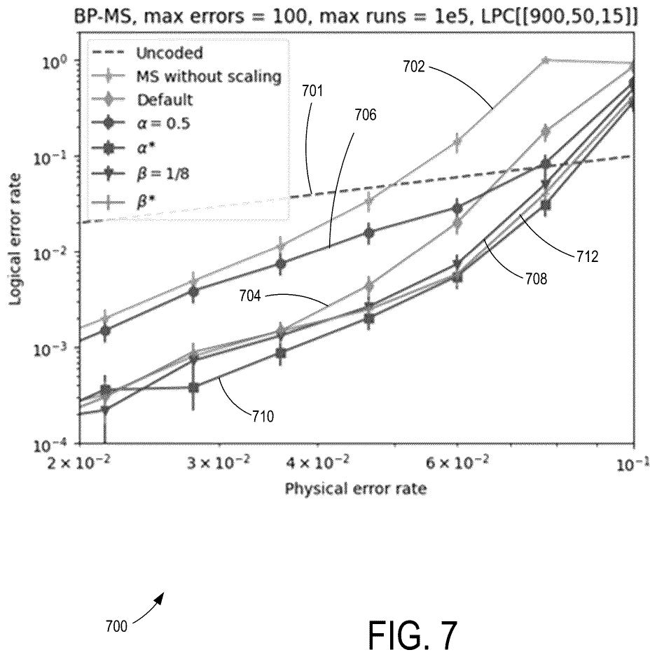

FIG. 6 and FIG. 7 are graphs 600, 700 showing example logical error rates achieved when decoding QLDPC codes using belief propagation. The label, LPC, means the codes are Lifted Product Codes, which refers to the way they are constructed. More specifically, FIG. 6 shows the results for a QLDPC code with N=1054, k=140 and d=20, in which d is the code distance. FIG. 7 shows the results for a QLDPC code with N=900, k=50 and d=15. In both figures, the dashed lines 601, 701 show the logical error rate that would be achieved if no encoding is used. The lines 602, 702 show the logical error rate using the MSA with no scaling. The lines 604, 704, labelled “Default”, show the logical error rate achieved in scaled MSA with the scaling factor given as in Equation 2 discussed hereinabove. The lines 606, 706 show the logical error rates assuming particular values of a and 608, 708 show the logical error rates assuming particular values of β. The results obtained by optimizing α using the methods described hereinabove are shown by lines 610, 710 and results obtained by optimizing β using the methods described hereinabove are shown by lines 612, 712. As illustrated, using the optimized values of α and β (labelled α* and β*) reduces the logical error rate compared to the arbitrarily chosen values.

### CONCLUDING REMARKS

Having described and illustrated the principles of the disclosed technology with reference to the illustrated embodiments, it will be recognized that the illustrated embodiments can be modified in arrangement and detail without departing from such principles. For instance, elements of the illustrated embodiments shown in software may be implemented in hardware and vice-versa. Also, the technologies from any example can be combined with the technologies described in any one or more of the other examples. It will be appreciated that procedures and functions such as those described with reference to the illustrated examples can be implemented in a single hardware or software module, or separate modules can be provided. The particular arrangements above are provided for convenient illustration, and other arrangements can be used.

In view of the many possible embodiments to which the principles of the disclosed technology may be applied, it should be recognized that the illustrated embodiments are only preferred examples of the invention and should not be taken as limiting the scope of the disclosed technology. Rather, the scope is defined by the following claims. We therefore claim all that comes within the scope of these claims.

We claim:

1. A method, comprising:
obtaining a syndrome based on a stabilizer measurement performed on a set of qubits, wherein the set of qubits is encoded based on a code that is representable as a set of variable nodes and a set of check nodes, wherein selected check nodes are coupled to selected variable nodes;
based on the syndrome, identifying errors in at least one of the qubits of the set of qubits using belief propagation based on a plurality of check node specific scaling factors αᵢ, wherein an Åh scaling factor αᵢ in the plurality of check node specific scaling factors is associated with an i^{th} check node in the set of check nodes.

2. The method of claim 1, further comprising, based on the identified error, correcting the identified error by applying at least one gate to the set of qubits or performing a classical operation.

3. The method of claim 1, wherein the check node specific scaling factors αᵢ are based on a number of variable nodes connected to the i^{th} check node.

4. The method of claim 1, wherein the using belief propagation comprises using scaled minimum sum algorithm (MSA) belief propagation.

5. The method of claim 4, wherein the plurality of check node specific scaling factors are selected to reduce a difference between messages determined at one or more check nodes using sum-product algorithm (SPA) and using scaled MSA with the plurality of check node specific scaling factors.

6. The method of claim 4, wherein the check node specific scaling factors αᵢ in each iteration of the belief propagation depend on an iteration number.

7. The method of claim 6, wherein the check node specific scaling factors αᵢ are determined as α=1−2^{-β}^{ᵢ}^{l}, wherein βᵢ is a constant associated with the i^{th} check node and l is an integer indicating the iteration number.

8. The method of claim 1, wherein the code is a quantum low density parity check (QLDPC) code or a quantum low density generator matrix (QLDGM) code.

9. The method of claim 1, further comprising:
selecting the plurality of check node specific scaling factors αᵢ based on a check nodes degree distribution of the code and a physical error rate of the set of qubits.

10. The method of claim 9, wherein selecting the plurality of check node specific scaling factors based on the check nodes degree distribution of the code and the physical error rate of the set of qubits comprises:
sending a request, the request comprising an indication of the check nodes degree distribution and the physical error rate; and
receiving, in response, an indication of the plurality of check node specific scaling factors.

11. The method of claim 9, wherein selecting the plurality of check node specific scaling factors based on the check nodes degree distribution of the code and the physical error rate of the set of qubits comprises:
retrieving, from a look-up table, the plurality of check node specific scaling factors based on the check nodes degree distribution and the physical error rate.

12. The method of claim 1, wherein the code is selected from a set of quantum error correction codes that are representable as the set of variable nodes and the set of check nodes, wherein the selected check nodes are coupled to the selected variable nodes.

13. A computer readable medium comprising stored computer executable instructions that, when executed by at least one processor of a system, will cause the system to:
obtain a syndrome based on a stabilizer measurement performed on a set of qubits, wherein the set of qubits is encoded based on a code that is representable as a set of variable nodes and a set of check nodes, wherein selected check nodes are coupled to selected variable nodes; and
based on the syndrome, identify errors in at least one of the qubits of the set of qubits using belief propagation based on a plurality of check node specific scaling factors αᵢ, wherein an i^{th} scaling factor αᵢ in the plurality of check node specific scaling factors is associated with an i^{th} check node in the set of check nodes.

14. The computer readable medium of claim 13, wherein the system is further caused to, based on the identified error, correct the identified error by applying at least one gate to the set of qubits or performing a classical operation.

15. The computer readable medium of claim 13, wherein the check node specific scaling factors αᵢ are based on a number of variable nodes connected to the ith check node.

16. The computer readable medium of claim 13, wherein using belief propagation comprises using scaled minimum sum algorithm (MSA) belief propagation.

17. A quantum device, comprising:
at least one processor; and
at least one process-readable memory coupled to the at least one processor and having stored thereon processor-executable instructions that, when executed by the at least one processor, will cause the quantum device to:
obtain a syndrome based on a stabilizer measurement performed on a set of qubits, wherein the set of qubits is encoded based on a code that is representable as a set of variable nodes and a set of check nodes, wherein selected check nodes are coupled to selected variable nodes; and
based on the syndrome, identify errors in at least one of the qubits of the set of qubits using belief propagation based on a plurality of check node specific scaling factors αᵢ, wherein an i^{th} scaling factor αᵢ in the plurality of check node specific scaling factors is associated with an i^{th} check node in the set of check nodes.

18. The quantum device of claim 17, wherein the quantum device is further caused to, based on the identified error, correct the identified error by applying at least one gate to the set of qubits or performing a classical operation.

19. The quantum device of claim 17, wherein the check node specific scaling factors αᵢ are based on a number of variable nodes connected to the i^{th} check node.

20. The quantum device of claim 17, wherein using belief propagation comprises using scaled minimum sum algorithm (MSA) belief propagation.
